(19) United States
(12) Patent Application Publication
(10) Pub. No.: US 2008/0258790 A1
(43) Pub. Date: Oct. 23, 2008

(54) Systems and Devices for Sub-threshold Data Capture

(75) Inventors: Charles M. Branch, Dallas, TX (US); Steven C. Bartling, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/736,419

(22) Filed: Apr. 17, 2007

(51) Int. Cl. H03K 3/0233

(52) U.S. Cl. 327/218

(57) ABSTRACT

Various systems and methods for capturing data are disclosed. For example, some embodiments of the present invention provide differential jam latches. Such differential jam latches include a data input, a latch input, and an output. Further, such differential jam latches include a PMOS stage and an NMOS stage. The PMOS stage includes a first PMOS transistor, a second PMOS transistor, a third PMOS transistor and a fourth PMOS transistor. The gate of the first PMOS transistor and the gate of the second PMOS transistor are electrically coupled to an inverted version of the latch input. The gate of the third PMOS transistor is electrically coupled to the data input, and the gate of the fourth PMOS transistor is electrically coupled to an inverted version of the data input. The NMOS stage includes a first NMOS transistor, a second NMOS transistor, a third NMOS transistor and a fourth NMOS transistor. The gate of the first NMOS transistor and the gate of the second NMOS transistor are electrically coupled to the latch input. The gate of the third NMOS transistor is electrically coupled to the data input, and the gate of the fourth NMOS transistor is electrically coupled to an inverted version of the data input. In addition, the jam latches include two inverters. The PMOS stage is electrically coupled to a first node and a second node, and the NMOS stage is electrically coupled to the first node and the second node. The first inverter drives an inverted version of the signal on the first node to the second node, and the second inverter drives an inverted version of the signal on the second node to the first node.

### BACKGROUND OF THE INVENTION

The present invention is related to data capture circuits, and more particularly to low voltage latch and flip-flop devices.

A number of different latch and flip-flop devices have been developed over the years. Most of these devices include a number of transistors that operate in one or both of the strong inversion or weak inversion regions. Such operation typically allows for input data to be stored at a very high frequency. However, such operation requires a substantial voltage differential between the upper and lower voltage rails powering the device. This constrains circuit design and consumes a substantial amount of power.

In some cases, traditional latch and flip-flop devices have been configured to operate in the sub-threshold region by, for example, reducing the voltage differential between the upper and lower voltage rails powering the devices. Such operation may provide for a substantial reduction in power consumption of the device, at a cost of greatly reducing the operational frequency of the device. Some simulations suggest that a traditional device operated in the sub-threshold region may operate two to three thousand times slower than corresponding operation in a strong inversion condition. This operational frequency penalty is often too high when compared with the power savings that may be achieved.

Thus, for at least the aforementioned reasons, there exists a need in the art for advanced systems and devices for registering data.

### BRIEF SUMMARY OF THE INVENTION

The present invention is related to data capture circuits, and more particularly to low voltage latch and flip-flop devices.

Some embodiments of the present invention provide differential jam latches Such differential jam latches include a data input, a latch input, and an output. Further, such differential jam latches include a PMOS stage and an NMOS stage. The PMOS stage includes a first PMOS transistor, a second PMOS transistor, a third PMOS transistor and a fourth PMOS transistor. The gate of the first PMOS transistor and the gate of the second PMOS transistor are electrically coupled to an inverted version of the latch input. The gate of the third PMOS transistor is electrically coupled to the data input, and the gate of the fourth PMOS transistor is electrically coupled to an inverted version of the data input. The NMOS stage includes a first NMOS transistor, a second NMOS transistor, a third NMOS transistor and a fourth NMOS transistor. The gate of the first NMOS transistor and the gate of the second NMOS transistor are electrically coupled to the latch input. The gate of the third NMOS transistor is electrically coupled to the data input, and the gate of the fourth NMOS transistor is electrically coupled to an inverted version of the data input. In addition, the jam latches include two inverters. The PMOS stage is electrically coupled to a first node and a second node, and the NMOS stage is electrically coupled to the first node and the second node. The first inverter drives an inverted version of the signal on the first node to the second node, and the second inverter drives an inverted version of the signal on the second node to the first node.

In some instances of the aforementioned embodiments, the source of the first PMOS transistor and the source of the second PMOS transistor are electrically coupled to an upper voltage rail. The drain of the first PMOS transistor is electrically coupled to the source of the third PMOS transistor, and the drain of the second PMOS transistor is electrically coupled to the source of the fourth PMOS transistor. The drain of the third PMOS transistor is electrically coupled to the first node, and the drain of the fourth PMOS transistor is electrically coupled to the second node. Further, the drain of the third NMOS transistor is electrically coupled to the first node, the drain of the fourth NMOS transistor is electrically coupled to the second node, the source of the third NMOS transistor is electrically coupled to the drain of the first NMOS transistor, the source of the fourth NMOS transistor is electrically coupled to the drain of the second NMOS transistor, and the source of the first NMOS transistor and the second NMOS transistor are electrically coupled to a lower voltage rail.

In one or more instances of the aforementioned embodiments, the source of the third PMOS transistor and the source of the fourth PMOS transistor are electrically coupled to an upper voltage rail. The drain of the third PMOS transistor is electrically coupled to the source of the first PMOS transistor, and the drain of the fourth PMOS transistor is electrically coupled to the source of the second PMOS transistor. The drain of the first PMOS transistor is electrically coupled to the first node, and the drain of the second PMOS transistor is electrically coupled to the second node. In some cases, the drain of the first NMOS transistor is electrically coupled to the first node, the drain of the second NMOS transistor is electrically coupled to the second node, the source of the first NMOS transistor is electrically coupled to the drain of the third NMOS transistor, the source of the second NMOS transistor is electrically coupled to the drain of the fourth NMOS transistor, and the source of the third NMOS transistor and the fourth NMOS transistor are electrically coupled to a lower voltage rail.

In some cases, the output is a differential output. A positive side of the differential output is electrically coupled to the first node, and a negative side of the differential output is electrically coupled to the second node. Some instances of the aforementioned embodiments include a pulse circuit. In such instances, the latch input is electrically coupled to the gates of the first PMOS transistor, the second PMOS transistor, the first NMOS transistor and the second NMOS transistor via the pulse circuit. In various instances of the aforementioned embodiments, the data input is driven by a multiplexer, and the multiplexer is operable to select between two sources for the data input.

Other embodiments of the present invention utilize differential jam latches in accordance with one or more embodiments of the present invention to D type flip-flops, to latches with pulsed clock inputs, to scan flip-flops, and the like. In some cases, the scan flip-flops include a multiplexed scan data input, while in other cases, the scan flip-flops include a scan input that is a modified differential jam latch.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several drawings to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a differential jam latch circuit in accordance with one or more embodiments of the present invention;

FIG. 2 shows a pulsed latch device utilizing the differential jam latch of FIG. 1 along with a multiplexed data input in accordance with various embodiments of the present invention;

FIG. 3 depicts a D flip-flop incorporating the differential jam latch of FIG. 1 in accordance with one or more embodiments of the present invention;

FIG. 4 shows a scan D-flip-flop incorporating another differential jam latch in accordance with other embodiments of the present invention; and

FIG. 5 depicts another scan D flip-flop incorporating the differential jam latch of FIG. 1 in accordance with some embodiments of the present invention.

### DETAILED DESCRIPTION OF THE INVENTION

The present invention is related to data capture circuits, and more particularly to low voltage latch and flip-flop devices.

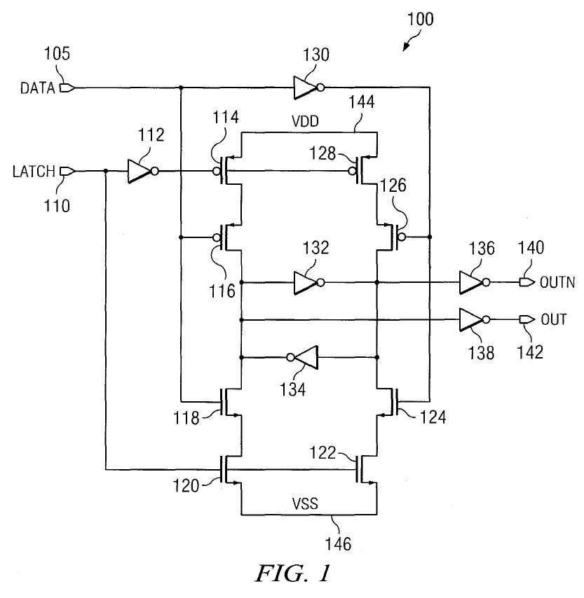

Turning to FIG. 1, a differential jam latch circuit 100 in accordance with one or more embodiments of the present invention is depicted. Differential jam latch circuit 100 includes a data input 105 and a latch input 110. Differential jam latch circuit 100 includes a positive output 142 and a negative output 140. The core of differential jam latch circuit 100 includes a group of PMOS transistors 114, 116, 126, 128; and a group of NMOS transistors 118, 120, 122, 124. In particular, the source of PMOS transistor 114 and the source of PMOS transistor 128 are electrically coupled to an upper power rail (VDD) 144. The gate of PMOS transistor 114 and the gate of PMOS transistor 128 are electrically coupled to an inverted version of latch input 110 (i.e., latch input 110 passed through an inverter 112). The drain of PMOS transistor 114 is electrically coupled to the source of PMOS transistor 116, and the drain of PMOS transistor 128 is electrically coupled to the source of PMOS transistor 126. The gate of PMOS transistor 116 is electrically coupled to data input 105, and the gate of PMOS transistor 126 is electrically coupled to an inverted version of data input 105 (i.e., data input 105 passed through an inverter 130).

The drain of PMOS transistor 116 is electrically coupled to the drain of PMOS transistor 126 via a set of inverters 132, 134. In particular, inverter 132 receives the signal at the drain of PMOS transistor 116, inverts the signal, and drives the inverted signal onto the drain of PMOS transistor 126. Similarly, inverter 134 receives the signal at the drain of PMOS transistor 126, inverts the signal, and drives the inverted signal onto the drain of PMOS transistor 116. In addition, the signal at the drain of PMOS transistor 126 is applied to an inverter 136 that in turn drives negative output 140, and the signal at the drain of PMOS transistor 116 is applied to an inverter 138 that in turn drives positive output 142.

The drain of PMOS transistor 116 is electrically coupled to the drain of NMOS transistor 118, and the drain of PMOS transistor 126 is electrically coupled to the drain of NMOS transistor 124. The gate of NMOS transistor 118 is electrically coupled to data input 105, and the gate of NMOS transistor 124 is electrically coupled to an inverted version of data input 105 (i.e., data input 105 passed through inverter 130). The source of NMOS transistor 118 is electrically coupled to the drain of NMOS transistor 120, and the source of NMOS transistor 124 is electrically coupled to the drain of NMOS transistor 122. The source of NMOS transistor 120 and the source of NMOS transistor 122 are each electrically coupled to a lower power rail (VSS) 146. The gate of NMOS transistor 120 and the gate of NMOS transistor 122 are each electrically coupled to latch input 110.

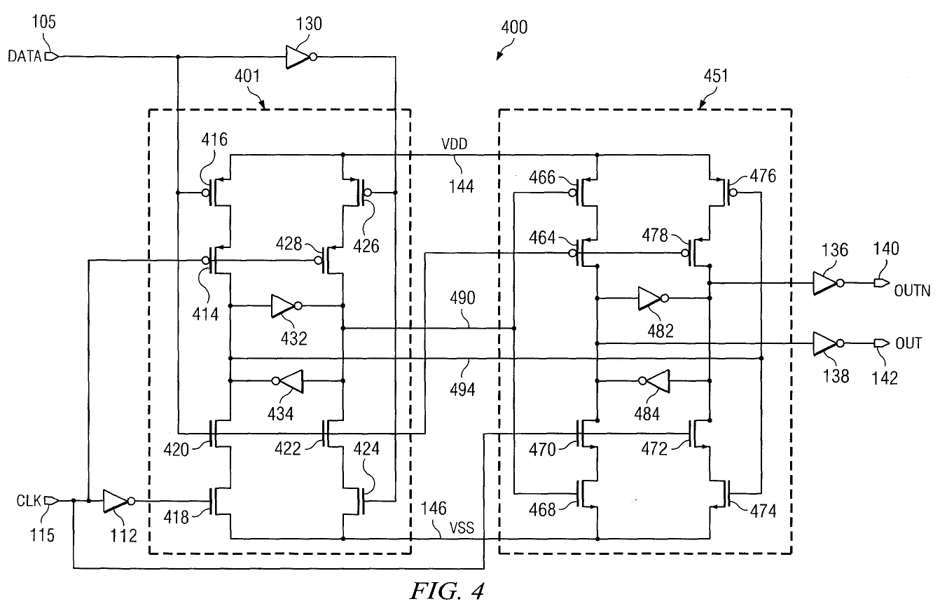

It should be noted that in other embodiments of the present invention (an example of which is shown in FIG. 4 below) PMOS transistor 114 may be swapped with PMOS transistor 116, PMOS transistor 128 may be swapped with PMOS transistor 126, NMOS transistor 118 may be swapped with NMOS transistor 120, and NMOS transistor 124 may be swapped with NMOS transistor 122. In this way, the inner transistor set is driven by the latch or clock input signal, and the outer transistor set is driven by the data input signal. Further, negative level sensitivity can be achieved by connecting latch input 110 directly to PMOS devices 114, 128, and connecting latch input 110 to NMOS devices 120, 122 via inverter 112.

In operation, the value applied to data input 105 is passed through as positive output 142 (and the inverse is apparent at negative output 140) whenever latch input 110 is asserted high. When latch input 110 is asserted low, the values at positive output 142 and negative output 140 are maintained or latched. In particular, when latch input 110 is asserted high, a logic ‘0’ is applied to the gates of PMOS transistor 114 and PMOS transistor 128 and a logic ‘1’ is applied to the gates of NMOS transistor 120 and NMOS transistor 122. This results in VDD−VSD at the sources of PMOS transistor 116 and PMOS transistor 126; and VSS+VSD at the sources of NMOS transistor 118 and NMOS transistor 124. VSD is the source to drain voltage drop of a transistor and in the simplified case is assumed to be the same for all of transistors 114, 116, 118, 120, 122, 124, 126. In this condition, when data input 105 is asserted as a logic ‘1’, the voltage at the drain of PMOS transistor 116 is VSS+2*VSD, and the voltage at the drain of PMOS transistor 126 is VDD−2*VSD. Proper operation of differential jam latch 100 is thus achieved where VDD−2*VSD is greater than VSS+2*VSD, or where VDD−VSS is greater than 2*VSD. Where the aforementioned condition is true, positive output 142 is asserted high relative to negative output 140 when data input 105 is asserted as a logic ‘1’. In contrast, when data input 105 is asserted as a logic ‘0’, the voltage at the drain of PMOS transistor 116 is VDD−2*VSD, and the voltage at the drain of PMOS transistor 126 is VSS+2*VSD. In this condition, positive output 142 is asserted low relative to negative output 140.

In contrast, when latch input 110 is asserted low, PMOS transistors 114, 128 and NMOS transistors 120, 122 are not conductive. In this condition, the voltages at the drain of PMOS transistor 116 and the drain of PMOS transistor 126 remain substantially at the level exhibited before latch input 110 transitioned from a logic ‘0’ to a logic ‘1’ due to charge build up in PMOS transistors 116, 126 and NMOS transistors 118, 124. Thus, where latch input 110 is asserted at a logic ‘0’, positive output 142 and negative output 140 are latched. In contrast, where latch output 110 is asserted at a logic ‘1’, positive output 142 and negative output 140 are transparent.

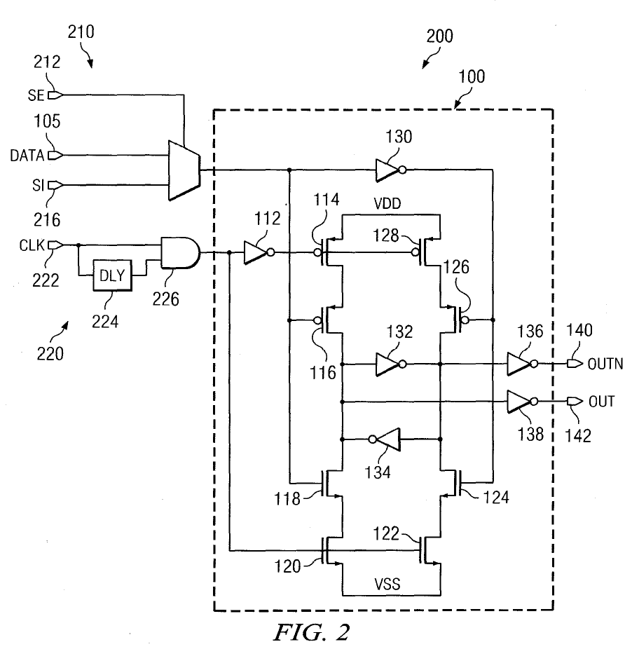

Turning to FIG. 2, a pulsed latch device 200 utilizing differential jam latch 100 (outlined in a dashed line) along with a multiplexed data input circuit 210 and a pulsed clock circuit 220 is depicted in accordance with various embodiments of the present invention. As shown, differential jam latch circuit 100 is that discussed above in relation to FIG. 1. Data input 105 discussed above in relation to FIG. 1 is applied to an input of multiplexed data input circuit 210. The other input of multiplexed data input circuit 210 has a scan input (SI) 216 applied thereto, and the selector input is driven by a scan select signal (SE) 212. In operation, when scan select signal 212 is asserted as a logic ‘0’, data input 105 is provided as the output of multiplexed data input circuit 210. When scan select signal 212 is asserted as a logic ‘1’, scan input 216 is provided as the output of multiplexed data input circuit 210.

Latch input 110 discussed in relation to FIG. 1 has been replaced by a clock signal 222 that drives pulsed clock circuit 220. By doing this, an edge triggered flip-flop is created from the latch described in FIG. 1. In particular, whenever clock input 222 is asserted as a logic ‘1’, the output of a AND gate 226 asserts high after a delay period 224 is satisfied and remains high for a period approximately equal to the period when clock input 222 is asserted high less delay period 224. Thus, each time clock input 222 is asserted at a logic ‘1’ a high asserted pulse is produced at the output of AND gate 226, otherwise, the output of AND gate 226 is asserted low.

In operation, when the output of multiplexed data input circuit 210 is asserted at a logic ‘1’, positive output 142 will be asserted high relative to negative output 140 shortly after (i.e., approximately delay period 224 after) clock input 222 is asserted high. Similarly, when the output of multiplexed data input circuit 210 is asserted at a logic ‘0’, positive output 142 will be asserted low relative to negative output 140 shortly after clock input 222 is asserted high. At all other times, the values at positive output 142 and negative output 140 are maintained at the state set during the prior pulse from pulsed clock circuit 220. Where the pulse output of pulsed clock circuit 220 is relatively short, circuit 200 operates similar to an edge triggered D flip-flop. It should be noted that pulsed clock circuit 220 is merely exemplary and that various other pulse generation circuits may be used in accordance with various embodiments of the present invention. For example, a pulse may be a low asserted pulse created by a NAND gate in place of the depicted AND gate. In such a case, inverter 112 may be applied to drive the gates of NMOS transistors 120, 122 instead of PMOS transistors. While different pulsing circuits may be used, the operation of circuit 200 may be substantially the same. Based on the disclosure provided herein, one of ordinary skill in the art will recognize a variety of pulsed clock circuits that may be used in relation to one or more embodiments of the present invention.

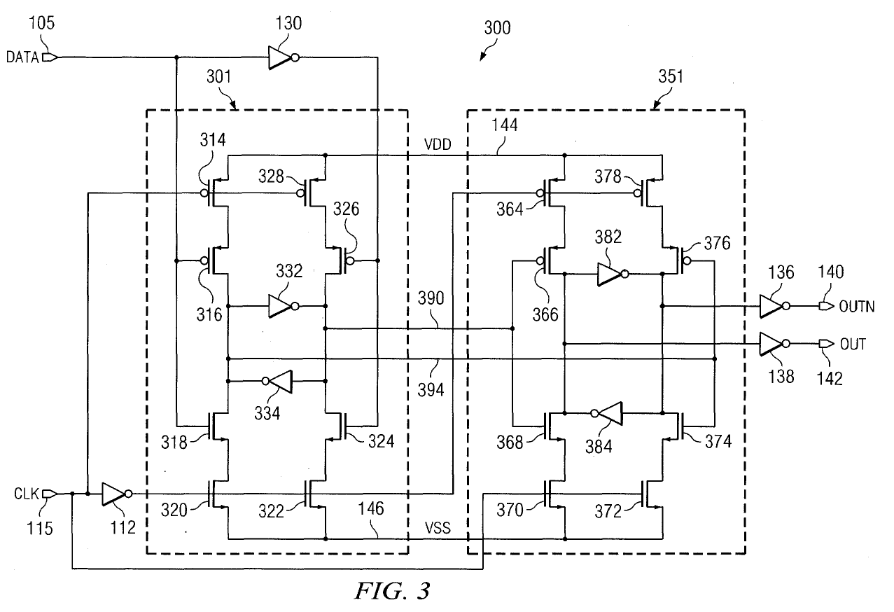

Turning to FIG. 3, a D flip-flop circuit 300 incorporating two differential jam latches 301, 351 (as shown in dashed lines) in accordance with one or more embodiments of the present invention is depicted. D flip-flop circuit 300 includes data input 105 and a clock input 115. In addition, D flip-flop circuit 300 includes positive output 142 and negative output 140.

Differential jam latch 301 includes a group of PMOS transistors 314, 316, 326, 328; and a group of NMOS transistors 318, 320, 322, 324. In particular, the source of PMOS transistor 314 and the source of PMOS transistor 328 are electrically coupled to upper power rail (VDD) 144. The gate of PMOS transistor 314 and the gate of PMOS transistor 328 are each electrically coupled to clock input 115. The drain of PMOS transistor 314 is electrically coupled to the source of PMOS transistor 316, and the drain of PMOS transistor 328 is electrically coupled to the source of PMOS transistor 326. The gate of PMOS transistor 316 is electrically coupled to data input 105, and the gate of PMOS transistor 326 is electrically coupled to an inverted version of data input 105 (i.e., data input 105 passed through inverter 130).

The drain of PMOS transistor 316 is electrically coupled to the drain of PMOS transistor 326 via a set of inverters 332, 334. In particular, inverter 332 receives the signal at the drain of PMOS transistor 316, inverts the signal, and drives the inverted signal onto the drain of PMOS transistor 326. Similarly, inverter 334 receives the signal at the drain of PMOS transistor 326, inverts the signal, and drives the inverted signal onto the drain of PMOS transistor 316. In addition, the signal at the drain of PMOS transistor 326 drives an input node 390 of differential jam latch 351, and the signal at the drain of PMOS transistor 316 drives an input node 394 of differential jam latch 351.

The drain of PMOS transistor 316 is electrically coupled to the drain of NMOS transistor 318, and the drain of PMOS transistor 326 is electrically coupled to the drain of NMOS transistor 324. The gate of NMOS transistor 318 is electrically coupled to data input 105, and the gate of NMOS transistor 324 is electrically coupled to an inverted version of data input 105 (i.e., data input 105 passed through inverter 130). The source of NMOS transistor 318 is electrically coupled to the drain of NMOS transistor 320, and the source of NMOS transistor 324 is electrically coupled to the drain of NMOS transistor 322. The source of NMOS transistor 320 and the source of NMOS transistor 322 are each electrically coupled to lower power rail (VSS) 146. The gate of NMOS transistor 320 and the gate of NMOS transistor 322 are each electrically coupled to clock input 115.

Differential jam latch 351 includes a group of PMOS transistors 364, 366, 376, 378; and a group of NMOS transistors 368, 370, 372, 374. In particular, the source of PMOS transistor 364 and the source of PMOS transistor 378 are electrically coupled to upper power rail (VDD) 144. The gate of PMOS transistor 364 and the gate of PMOS transistor 378 are each electrically coupled to an inverted version of clock input 115 (i.e., clock input 115 passed through inverter 112). The drain of PMOS transistor 364 is electrically coupled to the source of PMOS transistor 366, and the drain of PMOS transistor 378 is electrically coupled to the source of PMOS transistor 376. The gate of PMOS transistor 366 is electrically coupled to input node 390, and the gate of PMOS transistor 376 is electrically coupled to input node 394.

The drain of PMOS transistor 366 is electrically coupled to the drain of PMOS transistor 376 via a set of inverters 382, 384. In particular, inverter 382 receives the signal at the drain of PMOS transistor 366, inverts the signal, and drives the inverted signal onto the drain of PMOS transistor 376. Similarly, inverter 384 receives the signal at the drain of PMOS transistor 376, inverts the signal, and drives the inverted signal onto the drain of PMOS transistor 366. In addition, the signal at the drain of PMOS transistor 376 is applied to inverter 136 that in turn drives negative output 140, and the signal at the drain of PMOS transistor 366 is applied to inverter 138 that in turn drives positive output 142.

The drain of PMOS transistor 366 is electrically coupled to the drain of NMOS transistor 368, and the drain of PMOS transistor 376 is electrically coupled to the drain of NMOS transistor 374. The gate of NMOS transistor 368 is electrically coupled to input node 390, and the gate of NMOS transistor 374 is electrically coupled to input node 394. The source of NMOS transistor 368 is electrically coupled to the drain of NMOS transistor 370, and the source of NMOS transistor 374 is electrically coupled to the drain of NMOS transistor 372. The source of NMOS transistor 370 and the source of NMOS transistor 372 are each electrically coupled to a lower power rail (VSS) 146. The gate of NMOS transistor 370 and the gate of NMOS transistor 372 are each electrically coupled to clock input 115.

In operation, the value applied to data input 105 is latched as positive output 142 (and the inverse is apparent at negative output 140) upon the rising edge of clock input 115. In particular, when clock input 115 is asserted low, a logic ‘0’ is applied to the gates of PMOS transistor 314 and PMOS transistor 328 and a logic ‘1’ is applied to the gates of NMOS transistor 320 and NMOS transistor 322. This results in VDD-VSD at the sources of PMOS transistor 316 and PMOS transistor 326; and VSS+VSD at the sources of NMOS transistor 318 and NMOS transistor 324. As described above in relation to differential jam latch 100, proper operation of differential jam latch 301 is achieved where VDD−2*VSD is greater than VSS+2*VSD, or where VDD−VSS is greater than 2*VSD. Where the aforementioned condition is true, input node 390 is asserted high relative to input node 394 when data input 105 is asserted as a logic ‘1’. In contrast, when data input 105 is asserted as a logic ‘0’, the voltage at the drain of PMOS transistor 316 is VDD−2*VSD, and the voltage at the drain of PMOS transistor 326 is VSS+2*VSD. In this condition, input node 390 is asserted low relative to input node 394.

In contrast, when clock input 115 is asserted high, PMOS transistors 314, 328 and NMOS transistors 320, 322 are not conductive. In this condition, the voltages at the drain of PMOS transistor 316 and the drain of PMOS transistor 326 remain substantially at the level exhibited before clock input 115 transitioned from a logic ‘1’ to a logic ‘0’ due to charge build up in PMOS transistors 316, 326 and NMOS transistors 318, 324.

When clock input 115 is asserted high, a logic ‘0’ is applied to the gates of PMOS transistor 364 and PMOS transistor 378 and a logic ‘1’ is applied to the gates of NMOS transistor 370 and NMOS transistor 372. This results in VDD-VSD at the sources of PMOS transistor 366 and PMOS transistor 376; and VSS+VSD at the sources of NMOS transistor 368 and NMOS transistor 374. Where VDD−VSS is greater than 2*VSD, positive output 142 is asserted high relative to negative output 140 when input node 390 is asserted high relative to input node 394 (i.e., when data input 105 was asserted high during the low assertion period of clock input 115). In contrast, when input node 390 is asserted low relative to input node 394 (i.e., when data input 105 was asserted low during the low assertion period of clock input 115), positive output 142 is asserted low relative to negative output 140.

In contrast, when clock input 115 is asserted low, PMOS transistors 364, 378 and NMOS transistors 370, 372 are not conductive. In this condition, the voltages at the drain of PMOS transistor 366 and the drain of PMOS transistor 376 remain substantially at the level exhibited before clock input 115 transitioned from a logic ‘1’ to a logic ‘0’ due to charge build up in PMOS transistors 366, 376 and NMOS transistors 368, 374.

It should be noted that in some embodiments of the present invention that D flip-flop circuit 300 may be converted into a scan flip-flop by adding a multiplexer that drives data input 105. The multiplexer includes a scan input, a data input, and a selector to select between the scan input and the data input. Based on the disclosure provided herein, one of ordinary skill in the art will recognize other modifications that may be made to D flip-flop circuit 300 to achieve different operational characteristics in accordance with one or more embodiments of the present invention.

Turning to FIG. 4, a D flip-flop circuit 400 incorporating two differential jam latches 401, 451 (as shown in dashed lines) in accordance with other embodiments of the present invention is depicted. Similar to that discussed above in relation to FIG. 3, D flip-flop circuit 400 includes data input 105 and a clock input 115, and positive output 142 and negative output 140. In contrast to circuit 300, D flip-flop circuit 400 includes use of differential jam latches where the inner transistor set is driven by clock input signal 115, and the outer transistor set is driven by the data input signal 105 (either directly or indirectly).

Differential jam latch 401 includes a group of PMOS transistors 414, 416, 426, 428; and a group of NMOS transistors 418, 420, 422, 424. In particular, the source of PMOS transistor 416 and the source of PMOS transistor 426 are electrically coupled to upper power rail (VDD) 144. The gate of PMOS transistor 416 is electrically coupled to data input 105, and the gate of PMOS transistor 426 is electrically coupled to an inverted version of data input 105 (i.e., data input 105 passed through inverter 130). The drain of PMOS transistor 416 is electrically coupled to the source of PMOS transistor 414, and the drain of PMOS transistor 426 is electrically coupled to the source of PMOS transistor 428.

The drain of PMOS transistor 414 is electrically coupled to the drain of PMOS transistor 428 via a set of inverters 432, 434. In particular, inverter 432 receives the signal at the drain of PMOS transistor 414, inverts the signal, and drives the inverted signal onto the drain of PMOS transistor 428. Similarly, inverter 434 receives the signal at the drain of PMOS transistor 428, inverts the signal, and drives the inverted signal onto the drain of PMOS transistor 414. In addition, the signal at the drain of PMOS transistor 428 drives an input node 490 of differential jam latch 451, and the signal at the drain of PMOS transistor 414 drives an, input node 494 of differential jam latch 451. The gate of PMOS transistor 414 and the gate of PMOS transistor 428 are each electrically coupled to clock input 115.

The drain of PMOS transistor 414 is electrically coupled to the drain of NMOS transistor 420, and the drain of PMOS transistor 422 is electrically coupled to the drain of NMOS transistor 424. The gate of NMOS transistor 420 and the gate of NMOS transistor 422 are each electrically coupled to clock input 115. The gate of NMOS transistor 418 is electrically coupled to data input 105, and the gate of NMOS transistor 424 is electrically coupled to an inverted version of data input 105 (i.e., data input 105 passed through inverter 130). The source of NMOS transistor 418 and the source of NMOS transistor 424 are each electrically coupled to lower power rail (VSS) 146.

Differential jam latch 451 includes a group of PMOS transistors 464, 466, 476, 478; and a group of NMOS transistors 468, 470, 472, 474. In particular, the source of PMOS transistor 466 and the source of PMOS transistor 476 are electrically coupled to upper power rail (VDD) 144. The gate of PMOS transistor 466 is electrically coupled to input node 490, and the gate of PMOS transistor 476 is electrically coupled to input node 494. The drain of PMOS transistor 466 is electrically coupled to the source of PMOS transistor 464, and the drain of PMOS transistor 476 is electrically coupled to the source of PMOS transistor 478. The gate of PMOS transistor 464 and the gate of PMOS transistor 478 are each electrically coupled to an inverted version of clock input 115 (i.e., clock input 115 passed through inverter 112).

The drain of PMOS transistor 464 is electrically coupled to the drain of PMOS transistor 478 via a set of inverters 482, 484. In particular, inverter 482 receives the signal at the drain of PMOS transistor 464, inverts the signal, and drives the inverted signal onto the drain of PMOS transistor 478. Similarly, inverter 484 receives the signal at the drain of PMOS transistor 478, inverts the signal, and drives the inverted signal onto the drain of PMOS transistor 464. In addition, the signal at the drain of PMOS transistor 478 is applied to inverter 136 that in turn drives negative output 140, and the signal at the drain of PMOS transistor 464 is applied to inverter 138 that in turn drives positive output 142.

The drain of PMOS transistor 464 is electrically coupled to the drain of NMOS transistor 470, and the drain of PMOS transistor 478 is electrically coupled to the drain of NMOS transistor 472. The gate of NMOS transistor 470 and the gate of NMOS transistor 472 are each electrically coupled to clock input 115. The source of NMOS transistor 470 is electrically coupled to the drain of NMOS transistor 468, and the source of NMOS transistor 472 is electrically coupled to the drain of NMOS transistor 474. The gate of NMOS transistor 468 is electrically coupled to input node 490, and the gate of NMOS transistor 474 is electrically coupled to input node 494. The source of NMOS transistor 468 and the source of NMOS transistor 474 are each electrically coupled to a lower power rail (VSS) 146.

In operation, the value applied to data input 105 is latched as positive output 142 (and the inverse is apparent at negative output 140) upon the rising edge of clock input 115. In particular, when data input 105 is asserted high, a logic ‘1’ is applied to the gates of PMOS transistor 416 and NMOS transistor 418, and a logic ‘0’ is applied to the gates of PMOS transistor 426 and NMOS transistor 424. In this condition, when clock input 115 is asserted low, VDD−2*VSD will be exhibited at input node 490 and VSS+2*VSD will be exhibited at input node 494. As described above in relation to differential jam latch 100, proper operation of differential jam latch 401 is achieved where VDD−2*VSD is greater than VSS+2*VSD, or where VDD−VSS is greater than 2*VSD. Where the aforementioned condition is true, input node 490 is asserted high relative to input node 494 when data input 105 is asserted as a logic ‘1’. In contrast, when data input 105 is asserted as a logic ‘0’ and clock input 115 is asserted low, input node 490 is asserted low relative to input node 494. When clock input 115 is asserted high, PMOS transistors 414, 428 and NMOS transistors 420, 422 are not conductive. In this condition, the voltages at the drain of PMOS transistor 414 and the drain of PMOS transistor 428 remain substantially at the level exhibited before clock input 115 transitioned from a logic ‘1’ to a logic ‘0’ due to charge build up in PMOS transistors 414, 428 and NMOS transistors 420, 422.

When input node 490 is asserted high relative to input node 494 and clock input 115 is asserted high, VSS+2*VSD will be exhibited at the drain of PMOS transistor 464 and VDD−2*VSD will be exhibited at the drain of PMOS transistor 478. Where VDD−VSS is greater than 2*VSD, positive output 142 is asserted high relative to negative output 140 when input node 490 is asserted high relative to input node 494 (i.e., when data input 105 was asserted high during the low assertion period of clock input 115). In contrast, when input node 490 is asserted low relative to input node 494 (i.e., when data input 105 was asserted low during the low assertion period of clock input 115), positive output 142 is asserted low relative to negative output 140.

When clock input 115 is asserted low, PMOS transistors 464, 478 and NMOS transistors 470, 472 are not conductive. In this condition, the voltages at the drain of PMOS transistor 464 and the drain of PMOS transistor 478 remain substantially at the level exhibited before clock input 115 transitioned from a logic ‘1’ to a logic ‘0’ due to charge build up in PMOS transistors 464, 478 and NMOS transistors 470, 472.

It should be noted that in some embodiments of the present invention that D flip-flop circuit 400 may be converted into a scan flip-flop by adding a multiplexer that drives data input 105. The multiplexer includes a scan input, a data input, and a selector to select between the scan input and the data input. Based on the disclosure provided herein, one of ordinary skill in the art will recognize other modifications that may be made to D flip-flop circuit 400 to achieve different operational characteristics in accordance with one or more embodiments of the present invention.

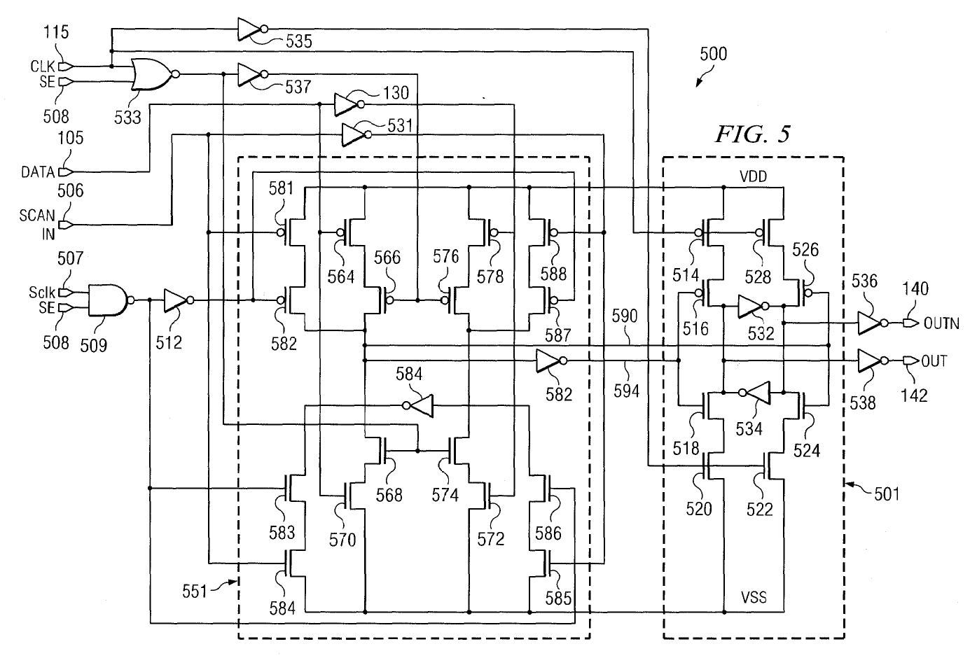

Turning to FIG. 5, a scan D flip-flop 500 incorporating a differential jam latch 501 (as shown in dashed lines) and a scan latch 551 (as shown in dashed lines) in accordance with some embodiments of the present invention is depicted. Scan D flip-flop 500 includes data input 105, a scan input 506 clock input 115, a scan select input (SE) 508, and a scan clock 507. In addition, D flip-flop circuit 500 includes positive output 142 and negative output 140.

Differential jam latch 501 includes a group of PMOS transistors 514, 516, 526, 528; and a group of NMOS transistors 518, 520, 522, 524. In particular, the source of PMOS transistor 514 and the source of PMOS transistor 528 are electrically coupled to upper power rail (VDD) 144. The gate of PMOS transistor 514 and the gate of PMOS transistor 528 are electrically coupled to clock input 115. The drain of PMOS transistor 514 is electrically coupled to the source of PMOS transistor 516, and the drain of PMOS transistor 528 is electrically coupled to the source of PMOS transistor 526. The gate of PMOS transistor 516 is electrically coupled to an input node 594, and the gate of PMOS transistor 526 is electrically coupled to an input node 590.

The drain of PMOS transistor 516 is electrically coupled to the drain of PMOS transistor 526 via a set of inverters 532, 534. In particular, inverter 532 receives the signal at the drain of PMOS transistor 516, inverts the signal, and drives the inverted signal onto the drain of PMOS transistor 526. Similarly, inverter 534 receives the signal at the drain of PMOS transistor 526, inverts the signal, and drives the inverted signal onto the drain of PMOS transistor 516. In addition, the signal at the drain of PMOS transistor 526 is applied to an inverter 536 that in turn drives negative output 140, and the signal at the drain of PMOS transistor 516 is applied to an inverter 538 that in turn drives positive output 142.

The drain of PMOS transistor 516 is electrically coupled to the drain of NMOS transistor 518, and the drain of PMOS transistor 526 is electrically coupled to the drain of NMOS transistor 524. The gate of NMOS transistor 518 is electrically coupled to input node 594, and the gate of NMOS transistor 524 is electrically coupled to input node 590. The source of NMOS transistor 518 is electrically coupled to the drain of NMOS transistor 520, and the source of NMOS transistor 524 is electrically coupled to the drain of NMOS transistor 522. The source of NMOS transistor 520 and the source of NMOS transistor 522 are each electrically coupled to lower power rail (VSS) 146. The gate of NMOS transistor 520 and the gate of NMOS transistor 522 are each electrically coupled to an inverted version of clock input 115 (i.e., clock input 115 passed through an inverter 535).

Scan jam latch 551 includes an inner data latch portion and an outer scan latch portion as discussed more fully below. The data latch portion includes a group of PMOS transistors 564, 566, 576, 578; and a group of NMOS transistors 568, 570, 572, 574. In particular, the source of PMOS transistor 564 and the source of PMOS transistor 578 are electrically coupled to upper power rail (VDD) 144. The gate of PMOS transistor 564 is electrically coupled to data input 105, and the gate of PMOS transistor 578 is electrically coupled to an inverted version of data input 105 (i.e., data input 105 passed through inverter 130). The drain of PMOS transistor 564 is electrically coupled to the source of PMOS transistor 566, and the drain of PMOS transistor 578 is electrically coupled to the source of PMOS transistor 576. The gate of PMOS transistor 566 and the gate of PMOS transistor 576 are each electrically coupled to clock input 115 via a NOR gate 533 and an inverter 537.

The drain of PMOS transistor 566 is electrically coupled to the drain of PMOS transistor 576 via a set of inverters 582, 584. In particular, inverter 582 receives the signal at the drain of PMOS transistor 566, inverts the signal, and drives the inverted signal onto the drain of PMOS transistor 576. Similarly, inverter 584 receives the signal at the drain of PMOS transistor 576, inverts the signal, and drives the inverted signal onto the drain of PMOS transistor 566. In addition, the signal at the drain of PMOS transistor 576 drives input node 594 and the signal at the drain of PMOS transistor 566 drives input node 590.

The drain of PMOS transistor 566 is electrically coupled to the drain of NMOS transistor 568, and the drain of PMOS transistor 576 is electrically coupled to the drain of NMOS transistor 574. The gate of NMOS transistor 568 and the gate of NMOS transistor 574 are each electrically coupled to an inverted version of input clock 115 (i.e., input clock passed through NOR gate 533). The source of NMOS transistor 568 is electrically coupled to the drain of NMOS transistor 570, and the source of NMOS transistor 574 is electrically coupled to the drain of NMOS transistor 572. The source of NMOS transistor 570 and the source of NMOS transistor 572 are each electrically coupled to lower power rail (VSS) 146. The gate of NMOS transistor 570 is electrically coupled to data input 105, and the gate of NMOS transistor 572 is electrically coupled to an inverted version of data input 105 (i.e., data input 105 passed through inverter 130).

The scan latch portion includes a group of PMOS transistors 581, 582, 587, 588; and a group of NMOS transistors 583, 584, 585, 586. In particular, the source of PMOS transistor 581 and the source of PMOS transistor 588 are each electrically coupled to upper power rail (VDD) 144. The gate of PMOS transistor 581 is electrically coupled to scan input 506, and the gate of PMOS transistor 588 is electrically coupled to an inverted version of scan input 506 (i.e., scan input 506 passed through an inverter 531). The drain of PMOS transistor 581 is electrically coupled to the source of PMOS transistor 582, and the drain of PMOS transistor 588 is electrically coupled to the source of PMOS transistor 587. The gate of PMOS transistor 582 and the gate of PMOS transistor 587 are each electrically coupled to an inverted version of scan clock input 507 (i.e., scan clock input passed through an AND gate 509 and an inverter 512).

The drain of PMOS transistor 582 is electrically coupled to the drain of PMOS transistor 587 via the set of inverters 582, 584. In particular, inverter 582 receives the signal at the drain of PMOS transistor 582, inverts the signal, and drives the inverted signal onto the drain of PMOS transistor 587. Similarly, inverter 584 receives the signal at the drain of PMOS transistor 587, inverts the signal, and drives the inverted signal onto the drain of PMOS transistor 582. In addition, the signal at the drain of PMOS transistor 587 drives input node 594 and the signal at the drain of PMOS transistor 582 drives input node 590.

The drain of PMOS transistor 582 is electrically coupled to the drain of NMOS transistor 583, and the drain of PMOS transistor 587 is electrically coupled to the drain of NMOS transistor 586. The gate of NMOS transistor 583 and the gate of NMOS transistor 586 are each electrically coupled to scan clock input 507 via AND gate 509. The source of NMOS transistor 583 is electrically coupled to the drain of NMOS transistor 584, and the source of NMOS transistor 586 is electrically coupled to the drain of NMOS transistor 585. The source of NMOS transistor 584 and the source of NMOS transistor 585 are each electrically coupled to lower power rail (VSS) 146. The gate of NMOS transistor 584 is electrically coupled to scan input 506, and the gate of NMOS transistor 585 is electrically coupled to an inverted version of scan input 506 (i.e., scan input 506 passed through inverter 531).

In operation, when scan select input 508 is asserted high, the scan latch portion of scan latch 551 drives input nodes 590, 594. Alternatively, when scan select input 508 is asserted low, the data latch portion of scan latch 551 drives input nodes 590, 594. In particular, when scan select input 508 is asserted high and scan clock input 507 is asserted high, input node 594 is asserted high relative to input node 590 when scan input 506 is asserted high. When scan select input 508 is asserted high and scan clock input 507 is asserted high, input node 594 is asserted low relative to input node 590 when scan input 506 is asserted low. When scan select input 508 is asserted high and scan clock input 507 is asserted low, the values previously on input nodes 590, 594 are retained. Alternatively, when scan select input 508 is asserted low and clock input signal 115 is asserted low, input node 594 is asserted high relative to input node 590 when data input 105 is asserted high. When scan select input 508 is asserted low and clock input signal 115 is asserted low, input node 594 is asserted low relative to input node 590 when data input 105 is asserted low. When scan select input 508 is asserted low and clock input 115 is asserted high, the values previously on input nodes 590, 594 are retained. The values on input nodes 590, 594 propagate through differential jam latch 501 as previously described herein.

In conclusion, the present invention provides novel systems, devices, methods for data capture. While detailed descriptions of one or more embodiments of the invention have been given above, various alternatives, modifications, and equivalents will be apparent to those skilled in the art without varying from the spirit of the invention. For example, while the described embodiments each include single ended inputs, other embodiments in accordance with the present invention may include either or both of differential data and clock inputs. Therefore, the above description should not be taken as limiting the scope of the invention, which is defined by the appended claims.

What is claimed is:

1. A D type flip-flop circuit, the circuit comprising:
a data input;
a clock input;
a first differential jam latch, wherein the first differential jam latch has first output, and wherein the data input and the clock input are electrically coupled to the first differential jam latch;
a second differential jam latch, wherein the second differential jam latch has a second output, wherein the clock input is electrically coupled to the second differential jam latch, and wherein the first output is electrically coupled to the second differential jam latch as an input;
wherein upon assertion of the clock input at one assertion level, the first differential jam latch is transparent and the second differential jam latch is latched; and
wherein upon assertion of the clock input at another assertion level, the first differential jam latch is latched and the second differential jam latch is transparent.

2. The circuit of claim 1, wherein the first differential jam latch comprises:
a PMOS stage, wherein the PMOS stage includes a first PMOS transistor, a second PMOS transistor, a third PMOS transistor and a fourth PMOS transistor; wherein the gate of the first PMOS transistor and the gate of the second PMOS transistor are electrically coupled to an inverted version of the latch input; wherein the gate of the third PMOS transistor is electrically coupled to the data input, and wherein the gate of the fourth PMOS transistor is electrically coupled to an inverted version of the data input; and
an NMOS stage, wherein the NMOS stage includes a first NMOS transistor, a second NMOS transistor, a third NMOS transistor and a fourth NMOS transistor;
wherein the gate of the first NMOS transistor and the gate of the second NMOS transistor are electrically coupled to the latch input; wherein the gate of the third NMOS transistor is electrically coupled to the data input, and wherein the gate of the fourth NMOS transistor is electrically coupled to an inverted version of the data input;
a first inverter;
a second inverter;
wherein the PMOS stage is electrically coupled to a first node and a second node, wherein the NMOS stage is electrically coupled to the first node and the second node, wherein the first inverter drives an inverted version of the signal on the first node to the second node, and wherein the second inverter drives an inverted version of the signal on the second node to the first node.

3. The circuit of claim 2, wherein the source of the first PMOS transistor and the source of the second PMOS transistor are electrically coupled to an upper voltage rail, wherein the drain of the first PMOS transistor is electrically coupled to the source of the third PMOS transistor, and wherein the drain of the second PMOS transistor is electrically coupled to the source of the fourth PMOS transistor, wherein the drain of the third PMOS transistor is electrically coupled to the first node, and wherein the drain of the fourth PMOS transistor is electrically coupled to the second node.

4. The circuit of claim 3, wherein the drain of the third NMOS transistor is electrically coupled to the first node, wherein the drain of the fourth NMOS transistor is electrically coupled to the second node, wherein the source of the third NMOS transistor is electrically coupled to the drain of the first NMOS transistor, wherein the source of the fourth NMOS transistor is electrically coupled to the drain of the second NMOS transistor, and wherein the source of the first NMOS transistor and the second NMOS transistor are electrically coupled to a lower voltage rail.

5. The circuit of claim 2, wherein the source of the third PMOS transistor and the source of the fourth PMOS transistor are electrically coupled to an upper voltage rail, wherein the drain of the third PMOS transistor is electrically coupled to the source of the first PMOS transistor, and wherein the drain of the fourth PMOS transistor is electrically coupled to the source of the second PMOS transistor, wherein the drain of the first PMOS transistor is electrically coupled to the first node, and wherein the drain of the second PMOS transistor is electrically coupled to the second node.

6. The circuit of claim 5, wherein the drain of the first NMOS transistor is electrically coupled to the first node, wherein the drain of the second NMOS transistor is electrically coupled to the second node, wherein the source of the first NMOS transistor is electrically coupled to the drain of the third NMOS transistor, wherein the source of the second NMOS transistor is electrically coupled to the drain of the fourth NMOS transistor, and wherein the source of the third NMOS transistor and the fourth NMOS transistor are electrically coupled to a lower voltage rail.

7. The circuit of claim 1, wherein the data input is a first data input, and wherein the circuit further comprises:
a second data input;
a scan data input;
a multiplexer, wherein a first input of the multiplexer is the second data input, the second input of the multiplexer is the scan input, and wherein the output of the multiplexer is the first data input.

8. A sub-threshold storage device, the storage device comprising:
a differential jam latch, wherein the differential jam latch includes a data input, a latch input, and an output; and wherein the differential jam latch includes:
a PMOS stage, wherein the PMOS stage includes a first PMOS transistor, a second PMOS transistor, a third PMOS transistor and a fourth PMOS transistor; wherein the gate of the first PMOS transistor and the gate of the second PMOS transistor are electrically coupled to an inverted version of the latch input; wherein the gate of the third PMOS transistor is electrically coupled to the data input, and wherein the gate of the fourth PMOS transistor is electrically coupled to an inverted version of the data input; and
an NMOS stage, wherein the NMOS stage includes a first NMOS transistor, a second NMOS transistor, a third NMOS transistor and a fourth NMOS transistor; wherein the gate of the first NMOS transistor and the gate of the second NMOS transistor are electrically coupled to the latch input; wherein the gate of the third NMOS transistor is electrically coupled to the data input, and wherein the gate of the fourth NMOS transistor is electrically coupled to an inverted version of the data input;
a first inverter;
a second inverter;
wherein the PMOS stage is electrically coupled to a first node and a second node, wherein the NMOS stage is electrically coupled to the first node and the second node, wherein the first inverter drives an inverted version of the signal on the first node to the second node, and wherein the second inverter drives an inverted version of the signal on the second node to the first node.

9. The device of claim 8, wherein the source of the first PMOS transistor and the source of the second PMOS transistor are electrically coupled to an upper voltage rail, wherein the drain of the first PMOS transistor is electrically coupled to the source of the third PMOS transistor, and wherein the drain of the second PMOS transistor is electrically coupled to the source of the fourth PMOS transistor, wherein the drain of the third PMOS transistor is electrically coupled to the first node, and wherein the drain of the fourth PMOS transistor is electrically coupled to the second node.

10. The device of claim 9, wherein the drain of the third NMOS transistor is electrically coupled to the first node, wherein the drain of the fourth NMOS transistor is electrically coupled to the second node, wherein the source of the third NMOS transistor is electrically coupled to the drain of the first NMOS transistor, wherein the source of the fourth NMOS transistor is electrically coupled to the drain of the second NMOS transistor, and wherein the source of the first NMOS transistor and the second NMOS transistor are electrically coupled to a lower voltage rail.

11. The device of claim 8, wherein the source of the third PMOS transistor and the source of the fourth PMOS transistor are electrically coupled to an upper voltage rail, wherein the drain of the third PMOS transistor is electrically coupled to the source of the first PMOS transistor, and wherein the drain of the fourth PMOS transistor is electrically coupled to the source of the second PMOS transistor, wherein the drain of the first PMOS transistor is electrically coupled to the first node, and wherein the drain of the second PMOS transistor is electrically coupled to the second node.

12. The device of claim 11, wherein the drain of the first NMOS transistor is electrically coupled to the first node, wherein the drain of the second NMOS transistor is electrically coupled to the second node, wherein the source of the first NMOS transistor is electrically coupled to the drain of the third NMOS transistor, wherein the source of the second NMOS transistor is electrically coupled to the drain of the fourth NMOS transistor, and wherein the source of the third NMOS transistor and the fourth NMOS transistor are electrically coupled to a lower voltage rail.

13. The device of claim 8, wherein the output is a differential output, wherein a positive side of the differential output is electrically coupled to the first node, and wherein a negative side of the differential output is electrically coupled to the second node.

14. The device of claim 8, wherein the device further includes:
a pulse circuit, wherein the latch input is electrically coupled to the gates of the first PMOS transistor, the second PMOS transistor, the first NMOS transistor and the second NMOS transistor via the pulse circuit.

15. The device of claim 8, wherein the data input is driven by a multiplexer, and wherein the multiplexer is operable to select between two sources for the data input.

16. A scan flip-flop circuit, wherein the circuit comprises:
a data input;
a scan input;
a clock input;
a scan latch, wherein the scan latch has first output; and wherein the data input, the scan input, and the clock input are electrically coupled to the scan latch as inputs;
a differential jam latch, wherein the differential jam latch has a second output, wherein the clock input is electrically coupled to the second differential jam latch as an input, and wherein the first output is electrically coupled to the second differential jam latch as an input;
wherein upon assertion of the clock input at a first assertion level, the scan latch is transparent and the differential jam latch is latched; and
wherein upon assertion of the clock input at a second assertion level, the scan jam latch is latched and the differential jam latch is transparent.

17. The circuit of claim 16, wherein the circuit further includes a scan select input; wherein upon assertion of the scan select input at a first assertion level, the scan input is loaded into the scan latch upon assertion of the clock input at the first assertion level; and upon assertion of the scan select input at a second assertion level, the scan input is loaded into the scan latch upon assertion of the clock input at the first assertion level.

18. The circuit of claim 17, wherein the scan latch includes:
a PMOS stage, wherein the PMOS stage includes a first PMOS transistor, a second PMOS transistor, a third PMOS transistor and a fourth PMOS transistor; wherein the gate of the first PMOS transistor and the gate of the second PMOS transistor are electrically coupled to an inverted version of the latch input; wherein the gate of the third PMOS transistor is electrically coupled to the data input, and wherein the gate of the fourth PMOS transistor is electrically coupled to an inverted version of the data input; and
an NMOS stage, wherein the NMOS stage includes a first NMOS transistor, a second NMOS transistor, a third NMOS transistor and a fourth NMOS transistor; wherein the gate of the first NMOS transistor and the gate of the second NMOS transistor are electrically coupled to the latch input; wherein the gate of the third NMOS transistor is electrically coupled to the data input, and wherein the gate of the fourth NMOS transistor is electrically coupled to an inverted version of the data input;
a first inverter;
a second inverter;
wherein the PMOS stage is electrically coupled to a first node and a second node, wherein the NMOS stage is electrically coupled to the first node and the second node, wherein the first inverter drives an inverted version of the signal on the first node to the second node, and wherein the second inverter drives an inverted version of the signal on the second node to the first node.

19. The circuit of claim 18, wherein the source of the first PMOS transistor and the source of the second PMOS transistor are electrically coupled to an upper voltage rail, wherein the drain of the first PMOS transistor is electrically coupled to the source of the third PMOS transistor, and wherein the drain of the second PMOS transistor is electrically coupled to the source of the fourth PMOS transistor, wherein the drain of the third PMOS transistor is electrically coupled to the first node, and wherein the drain of the fourth PMOS transistor is electrically coupled to the second node.

20. The circuit of claim 19, wherein the drain of the third NMOS transistor is electrically coupled to the first node, wherein the drain of the fourth NMOS transistor is electrically coupled to the second node, wherein the source of the third NMOS transistor is electrically coupled to the drain of the first NMOS transistor, wherein the source of the fourth NMOS transistor is electrically coupled to the drain of the second NMOS transistor, and wherein the source of the first NMOS transistor and the second NMOS transistor are electrically coupled to a lower voltage rail.
